(19) United States
(12) Patent Application Publication
(10) Pub. No.: US 2025/0300141 A1
(43) Pub. Date: Sep. 25, 2025

(54) TILED DISPLAY DEVICE

(71) Applicant: SAMSUNG ELECTRONICS CO., LTD., Suwon-si (KR)

(72) Inventors: Tatsuhiro SUWA, Yokohama (JP); Takashige FUJIMORI, Yokohama (JP); Atsuhito MURAI, Yokohama (JP)

(73) Assignee: SAMSUNG ELECTRONICS CO., LTD., Suwon-si (KR)

(21) Appl. No.: 19/231,077

(22) Filed: Jun. 6, 2025

Related U.S. Application Data
(63) Continuation of application No. PCT/KR2023/018779, filed on Nov. 21, 2023.

(30) Foreign Application Priority Data
Dec. 9, 2022 (JP) 2022-196784

(51) Int. Cl. H01L 25/07; H10H 29/30; H10H 29/80; H10H 29/853

(52) U.S. Cl. CPC H01L 25/072; H10H 29/30; H10H 29/842; H10H 29/853

(57) ABSTRACT

Provided is a tiled display device including modules adjacent to each other, each module including a substrate, a light emitting element on the substrate, an electrode configured to apply a voltage to the light emitting element, and a chamfered portion including a surface chamfered along a corner portion of each module of the modules, the chamfered portion being inclined with respect to a surface of the substrate, and a seam portion between adjacent modules of modules, the seam portion being filled with a transparent resin.

### CROSS-REFERENCE TO RELATED APPLICATIONS

This application is a bypass continuation of International Application No. PCT/KR2023/018779, filed on Nov. 21, 2023, which is based on and claims priority to Japanese Patent Application No. 2022-196784 filed on Dec. 9, 2022, in Japan Patent Office, the disclosures of which are incorporated by reference herein in their entireties BACKGROUND

### 1. FIELD

Embodiments of the present disclosure relate to a tiled display device.

### 2. DESCRIPTION OF RELATED ART

Tiled display devices generally include unit modules having a display unit with a light emitting element mounted on a substrate which are connected regularly side by side in a tile shape. The tiled display device is discussed as large-scale/scalable display technology, and is significantly challenged by a seam portion in the gap between adjacent modules.

A method for preventing the seam portion from being visible by forming a side black mask on the end surface of the seam portion of the LCD panel has been developed. Further, regarding visibility of the seam portion, transmitted light as well as reflection of external light need to be considered for transparent displays. For this reason, a transparent composite composition of glass and a transparent resin in which the Abbe number is greater than or equal to 45 or more (greater than or equal to 50), and the refractive indexes of the transparent resin and the glass are equal to or less than 0.01 (equal to or less than 0.005).

However, the method of using side black mask for polarizer-bonded LCDs cannot address the issues for transparent displays because of deterioration of transmittance due to the side black mask or deterioration of transparency due to incapability of controlling the dependency of refractive index difference on wavelengths which causes the seam portion to be easily viewed.

The transparent composite composition, despite a refractive index difference of equal to or less than 0.01 and an Abbe number of equal to or greater than 45, has the cases in which the refractive index difference increases with wavelengths, causing insufficient display transparency and may not secure sufficient seamlessness because the refraction of transmitted light passing through the seam portion or scattering of external light incident on the seam portion is recognized in an oblique direction. Further, seamlessness may be a characteristic in which there is no scattering of external light due to the reflection or scattering of the transmitted light at the seam portion between modules, such that the seam portion may be difficult to recognize.

Research to secure sufficient seamlessness and seamlessness at the seam portion by mitigating the deterioration of seamlessness due to refraction/scattering of the transmitted light and external light reflection at the seam portion in tiled display devices has been conducted. It may be possible to achieve seamlessness at the seam portion while securing sufficient seamlessness by controlling the refractive index difference in the visible light area of the module substrate and the transparent resin filling the seam portion to be within a specific range and limiting the interval between adjacent seam portions within a specific range.

A tiled display device that may achieve seamlessness at the seam portion while enhancing the seamlessness of the transmitted light and the reflected light at the seam portion is needed.

### SUMMARY

One or more embodiments provide a tiled display device having seamlessness at a seam portion and enhancing the seamlessness of the transmitted light and the reflected light at the seam portion.

According to an aspect of one or more embodiments, there is provided a tiled display device including modules adjacent to each other, each module including a substrate, a light emitting element on the substrate, an electrode configured to apply a voltage to the light emitting element, and a chamfered portion including a surface chamfered along a corner portion of each module of the modules, the chamfered portion being inclined with respect to a surface of the substrate, and a seam portion between adjacent modules of modules, the seam portion being filled with a transparent resin.

A refractive index difference between a refractive index of the substrate and a refractive index of the transparent resin in a visible wavelength band may be equal to or greater than −0.01 and equal to or less than 0.01, and a distance between the adjacent modules may be greater than 0 μm and equal to or less than 300 μm.

An angle between the processed surface of the chamfered portion and the surface of the substrate may be equal to or greater than 30° and equal to or less than 75°.

A protective layer may be on a surface of the substrate or two opposite surfaces of the substrate.

The tiled display device may further include a low-reflective portion on the seam portion filled with the transparent resin.

The low-reflective portion may be on at least one of a surface of the seam portion or a surface of the protective layer.

The transparent resin may be a colored transparent resin, and a difference between a transmittance of the seam portion and transmittance of the electrode may be equal to or greater than −10 and equal to or less than 10.

The tiled display device may further include a molding layer on the light emitting element, wherein a thickness of the molding layer may be equal to or less than half of a thickness of the substrate.

The transparent resin may be one of an epoxy resin, a silicone resin, an acrylic resin, and a combination thereof.

The protective layer may be a glass or an organic resin film.

The tiled display device may further include an adhesive layer adhering the protective layer to the substrate, the adhesive layer being one of an acrylic resin, a urethane resin, an epoxy resin, a silicone resin, and a combination thereof.

According to another aspect of one or more embodiments, there is provided a display device including modules adjacent to each other, each module including a substrate, a light emitting element on the substrate, an electrode configured to apply a voltage to the light emitting element, and a chamfered portion chamfered along a corner portion of the module, the chamfered portion including an inclined surface or a curved surface, and a transparent resin in an interval between adjacent modules of the modules, a refractive index difference between a refractive index of the substrate and a refractive index of the transparent resin in a visible wavelength band is equal to or greater than −0.01 and equal to or less than 0.01, and wherein interval distance between the adjacent modules is greater than 0 μm and equal to or less than 300 μm.

The chamfered portion may be inclined with respect to a surface of the substrate at an angle equal to or greater than 105 degrees and equal to or less than 150 degrees.

The tiled display device my further include a protective layer on a surface of the substrate or two opposite surfaces of the substrate.

According to still another aspect of one or more embodiments, there is provided an electronic device including modules adjacent to each other, each module including a substrate, a light emitting element on the substrate, an electrode configured to apply a voltage to the light emitting element, and a chamfered portion including a surface chamfered along a corner portion of each module of the modules, the chamfered portion being inclined with respect to a surface of the substrate, and a seam portion between adjacent modules of modules, the seam portion being filled with a transparent resin.

A refractive index difference between a refractive index of the substrate and a refractive index of the transparent resin in a visible wavelength band may be equal to or greater than −0.01 and equal to or less than 0.01, and a distance between the adjacent modules may be greater than 0 μm and equal to or less than 300 μm.

An angle between the processed surface of the chamfered portion and the surface of the substrate may be equal to or greater than 30° and equal to or less than 75°.

A protective layer may be on a surface of the substrate or two opposite surfaces of the substrate.

The electronic device may further include a low-reflective portion on the seam portion filled with the transparent resin.

The low-reflective portion may be on at least one of a surface of the seam portion or a surface of the protective layer.

### BRIEF DESCRIPTION OF DRAWINGS

Embodiments will be more clearly understood from the following detailed description taken in conjunction with the accompanying drawings in which:

FIG. 1 illustrates a plan view, a cross-sectional view taken along A-A, and a cross-sectional view taken along B-B of a tiled display device according to one or more embodiments;

FIG. 2 is a partial cross-sectional view of a seam portion of adjacent modules according to one or more embodiments;

FIG. 3 is a partial cross-sectional view illustrating a chamfered portion according to one or more embodiments;

FIG. 4 is a cross-sectional view illustrating that a molding layer is formed on a substrate according to one or more embodiments;

FIG. 5 is a plan view, a cross-sectional view taken along C-C, and a cross-sectional view taken along D-D of a tiled display device according to one or more other embodiments;

FIG. 6 is a cross-sectional view of a seam portion in which a molding layer and a protective layer are formed on a substrate according to one or more embodiments;

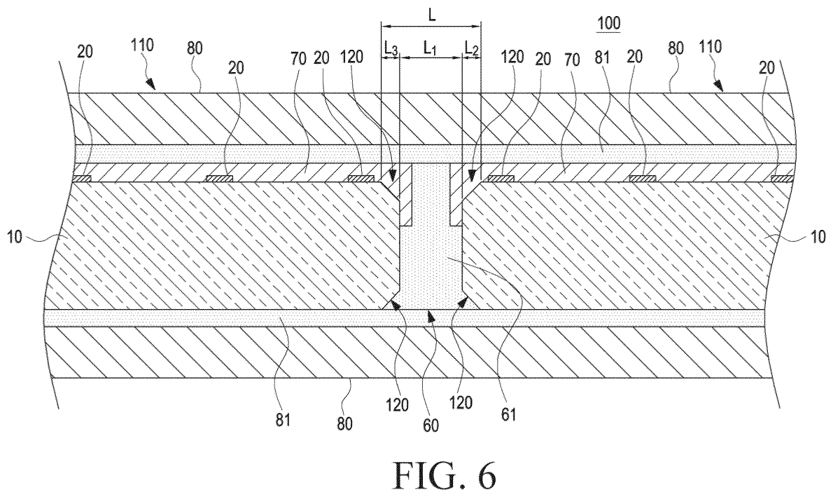

FIG. 7 is a view illustrating a method of forming a tile display device according to one or more embodiments;

FIG. 8 is a table illustrating specifications and evaluation results for the respective samples according to one or more embodiments;

FIG. 9 is a view illustrating a method of forming a tile display device according to one or more embodiments;

FIG. 10 is a table illustrating specifications and evaluation the respective samples according to one or more embodiments;

FIG. 11 is a view illustrating a method of forming a tile display device according to one or more embodiments;

FIG. 12 is a view illustrating a method of forming a tile display device according to one or more embodiments; and

FIG. 13 is a table illustrating specifications and evaluation the respective samples of according to one or more embodiments.

### DETAILED DESCRIPTION

Hereinafter, modes for practicing one or more embodiments are described in detail with reference to the drawings. The embodiments shown here are illustrative and are not limiting. Further, all other forms, embodiments, and operating techniques that may be implemented by one of ordinary skill in the art without departing from the gist of the embodiments are included in the scope and gist of the embodiments, and are included in the scope of the embodiments as defined in the claims and equivalents thereof.

Further, in the accompanying drawings, the scale, vertical and horizontal dimension ratio, and shape may be appropriately changed from those of the actual object for convenience of convenience, but they are merely examples and are not limiting.

Further, unless otherwise specified, operations and physical properties are measured under the conditions of room temperature, for example, equal to or greater than 20° C. and equal to or less than 25° C., and relative humidity of equal to or greater than 40% RH and equal to or less than 50% RH.

Further, in the following description, the ordinal numbers, such as “first” and “second,” are used for convenience, and do not define any specific order, unless otherwise specified.

One or more embodiments are directed to a tiled display device in which a plurality of modules (e.g., display modules or display panels) having a substrate, a light emitting element mounted on the substrate, and an electrode unit (electrode) applying a voltage to the light emitting element are regularly connected side by side in a tile shape, and a tiled display device in which a seam portion which is a gap between adjacent modules is filled with a transparent resin. The transparent resin may have a refractive index difference ΔRI that satisfies −0.01≤ΔRI≤0.01 in the visible wavelength band of the substrate and the transparent resin, and an interval (distance) L between adjacent modules may satisfy 0 μm<L≤300 μm.

According to one or more embodiments, the configuration of an LED display using an LED element as the light emitting element 20 is described. However, the tiled display device 100 is not limited to the LED display in the display type, but may also be applied to, for example, organic light emitting diode (OLED) displays, liquid crystal displays, or other types of display devices.

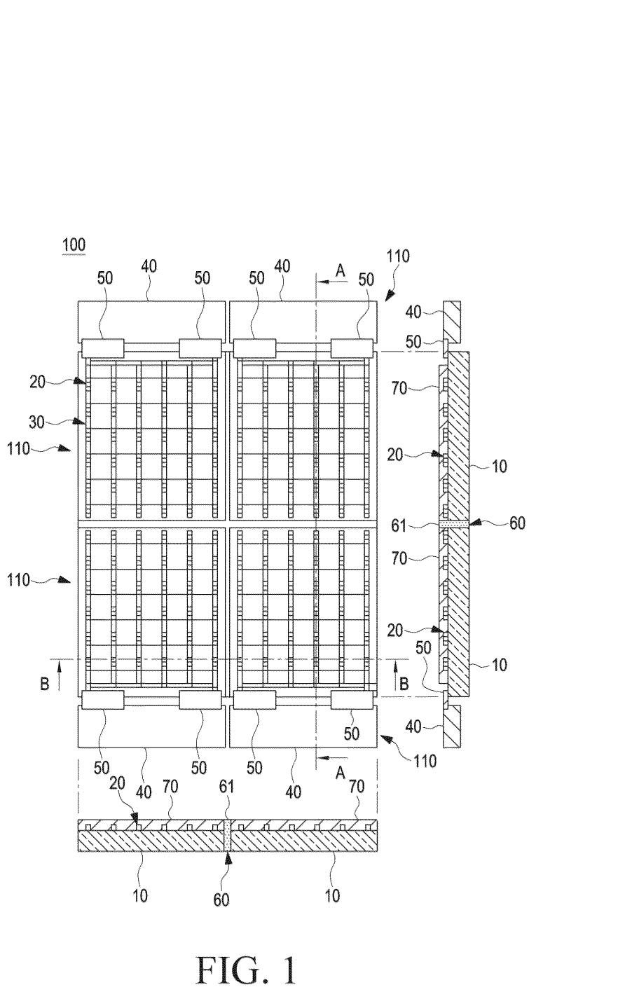

The configuration of the tiled display device 100 according to one or more embodiments is described with reference to FIGS. 1 to 5. However, FIGS. 1 to 5 relate to the tiled display device 100 according to one or more embodiments, however, embodiments are not limited to the configuration described with reference to the drawings.

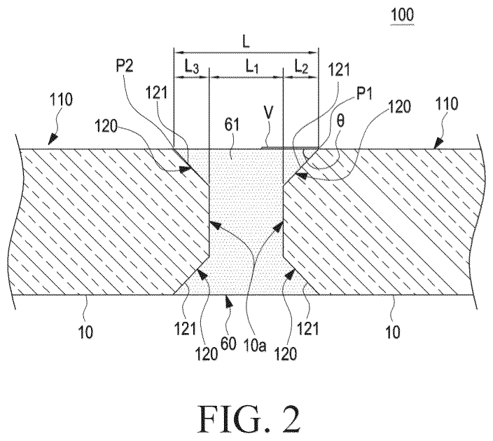

FIG. 1 is a plan view and a cross-sectional view of a tiled display device 100 according to one or more embodiments, and FIG. 2 is a partial cross-sectional view of a tiled display device 100. In FIG. 1, a plan view of the tiled display device 100, a cross-sectional view taken along line A-A, and a cross-sectional view taken along line B-B are illustrated.

In the tiled display device 100, as shown in FIG. 1, modules 110 including, at least, a substrate 10, a light emitting element 20 mounted on the substrate surface (surface) of the substrate 10, and an electrode unit 30 that applies the voltage required to drive the light emitting element 20 are arranged to have the same regularity as a matrix shape. A seam portion 60 which is a gap between the substrates 10 is interposed between the adjacent modules 110. FIG. 1 shows a form in which the modules 110 are arranged in 2×2. Further, the number of modules 110 arranged in the tiled display device 100 is not limited to FIG. 1, but they may be arranged in an arbitrary number.

As shown in FIG. 1, the tiled display device 100 has a driving circuit 40 and a flexible substrate 50 connecting the driving circuit 40 and the electrode unit 30. In the tiled display device 100, a predetermined driving voltage is applied to the electrode unit 30 through the flexible substrate 50 by the driving of the driving circuit 40. In the tiled display device 100, as a predetermined voltage is applied to the light emitting element 20 from the electrode unit 30, the light emitting element 20 emits light to display a predetermined display content.

The substrate 10 is formed of a material where the light emitting element 20 may be mounted, such as, for example, alkali-free glass, polyimide, PET, and silicon. As the alkali-free glass, a glass substrate may be suitably used. The substrate 10 is not limited to the above-described materials, and when mounting the light emitting element 20, an appropriate material may be arbitrarily selected considering the flatness of the mounting surface of the light emitting element 20 or heat resistance when mounting the light emitting element 20.

The light emitting element 20 is composed of LED elements for surface mounting of red, green, and blue colors, and is mounted on the substrate 10. The light emitting element 20 may include three color elements in each pixel of the substrate 10, and emits light by the voltage applied from the electrode unit 30.

The electrode unit 30 is composed of various lines connecting the light emitting element 20 and the flexible substrate 50 or a thin film transistors (TFT). The electrode unit 30 is connected to the driving circuit 40 through the flexible substrate 50, and applies a predetermined driving voltage to the light emitting element 20 based on the control of the driving circuit 40.

The tiled display device 100 may achieve the seamlessness of the seam portion 60 while enhancing the seamlessness of the reflected and transmitted light in the seam portion 60.

In the tiled display device 100, the transparent resin 61 fills the seam portion 60 between adjacent modules 110. The transparent resin 61 has a refractive index difference ΔRI in the range of −0.01≤ΔRI≤0.01 in the visible light area of the substrate 10 and the transparent resin 61, and the interval L between the adjacent modules 110 is 0 μm<L≤300 μm. For example, the transparent resin 61 fills (e.g., within about 300 μm) between the two adjacent modules 110 and may have a refractive index similar to a refractive index of the substrate 10 for visible wavelength band.

The refractive index difference ΔRI between the substrate 10 and the transparent resin 61 in the visible light area is −0.01≤ΔRI≤0.01, and the range may be −0.003≤ΔRI≤0.003 to enhance the seamlessness of the reflected and transmitted light in the seam portion 60 and achieve the seamlessness of the seam portion 60.

As shown in FIG. 2, the interval L between adjacent modules 110 is the distance between a boundary position P1 of the chamfered portion 120 and the surface of the substrate 10 in one adjacent module 110 and a boundary position P2 of the chamfered portion 120 and the surface of the substrate 10 in the other adjacent module 110. The interval L includes a first length L1, a second length L2, and a third length L3.

The first length L1 is the distance (inter-substrate distance) between the substrates 10 of the adjacent modules 110, as shown in FIG. 2. As shown in FIG. 2, the second length L2 is the distance between the end surface 10a of the substrate 10 in one adjacent module 110 and the chamfered portion 120 (corresponding to the chamfer width of the chamfered portion 120). As shown in FIG. 2, the third length L3 is the distance between the end surface 10a of the substrate 10 in the other adjacent module 110 and the chamfered portion 120 (corresponding to the chamfer width of the chamfered portion 120). As such, the interval L is the sum of the first length L1, which is the distance between the end surfaces 10a of the adjacent substrates 10, the second length L2, which is the chamfer width of the chamfered portion 120 of one substrate 10, and the third length L3, which is the chamfer width of the chamfered portion 120 of the other substrate 10.

The tiled display device 100 sets the interval L between the adjacent modules 110 to a range of 0 μm<L≤300 μm. Further, the first length L1 may be set in the range of 0 μm <L1<300 μm, the second length L2 in the range of 0 μm<L2<150 μm, and the third length L3 in the range of 0 μm<L3<150 μm. According to one or more embodiments, the sum of the first length L1, the second length L2, and the third length L3, e.g., the interval L, may be within about 300 μm.

Since the tiled display device 100 reduces restrictions on, e.g., the connection position of the light emitting element 20 as much as possible, the adjacent modules 110 may be arranged at equal intervals. Accordingly, the second length L2 and the third length L3 may be approximately the same. Further, approximately the same may indicate completely and substantially the same, and may include not only strictly equivalent, but also having a tolerance (about ±15 μm), or a state in which there is a difference at which the same function may be obtained.

The transparent resin 61 may be a resin having transparency in which a refractive index difference ΔRI in the visible wavelength band between the substrate 10 and the transparent resin 61 may be set in the range of −0.01≤ΔRI≤0.01. The transparent resin 61 may be formed of a resin from an epoxy resin, a silicone resin, an acrylic resin, and a combination thereof.

As the transparent resin 61, a product such as EHPE3150, Denacol EX-252, Denacol EX-141, Denacol EX-214L, etc., may be mixed with an appropriate amount of a curing agent, and the refractive index difference ΔRI in the visible wavelength band between the substrate 10 and the transparent resin 61 may be adjusted to the range of −0.01≤ΔRI≤0.01. Detailed examples of the combination or content of each material are described in the embodiments. Further, the transparent resin 61 may be a product in which the refractive index difference ΔRI in the visible wavelength band between the substrate 10 and the transparent resin 61 is in the range of −0.01≤ΔRI≤0.01.

In the tiled display device 100 according to one or more embodiments, it is necessary to control the refractive index in the visible wavelength band between the substrate 10 and the transparent resin 61 and the interval L between the adjacent modules 110 in the respective ranges described above. By controlling the range of ΔRI to the above-described range and setting the interval between the adjacent modules 110 to the above-described range, the tiled display device 100 may enhance the seamlessness of the reflected light and transmitted light in the seam portion 60, and achieve the seamlessness of the seam portion 60.

Here, controlling only one of the refractive index in the visible wavelength band between the substrate 10 and the transparent resin 61 and the interval L between the adjacent modules 110 to the above-described range may not enhance the seamlessness of the received light and the transmitted light in the seam portion 60 nor may it achieve seamlessness of the seam portion 60.

In the tiled display device 100, as the material filling the seam portion 60, a colored transparent resin colored with a predetermined color may fill the seam portion 60 instead of the transparent resin 61. As the colored transparent resin, one closer to the color of the electrode unit 30 may be in light of visibility and, as an example, a pigment or dye may be mixed to make it black, brown, or yellow according to the color of the electrode unit 30.

The colored transparent resin may be set to have a transmittance difference of the seam portion 60 and the electrode unit 30 is in the range of −10≤transmittance of seam portion 60−transmittance of electrode unit 30≤10 in order to achieve seamlessness of the seam portion 60 while enhancing the seamlessness of the reflected and transmitted light in the seam portion 60. For example, by controlling the deviation in transmittance between the seam portion 60 and the electrode unit 30 within 10% or less, seamlessness in the seam portion 60 containing colored transparent resin may be enhanced.

A chamfered portion 120 chamfered along the outer circumferential portion is formed at the corner portion 111 of the module 110 of the tiled display device 100. For the chamfered portion 120, chamfering may be performed using, for example, a rotating blade for chamfering.

As shown in FIG. 2, the angle θ formed by the virtual line V passing through the surface of the substrate 10 and the processed surface 121 of the chamfered portion 120 is in the range of 30°≤θ≤75° in light to achieve the seamlessness of the seam portion 60 and enhancing seamlessness, for example, in the range of 45°≤θ≤60° in light of processability, and may be 45° in light of strength. For example, the angle θ has a lower limit of 30°, or 45°. The angle θ has an upper limit of 75°, or 60°. According to one or more embodiments, the angle θ may refer to an inclination angle of the processed surface 121 of the chamfered portion 120 with respect to the plane including the surface of the substrate 10. According to one or more embodiments, the inclination angle of the processed surface 121 of the chamfered portion 120 with respect to the surface of the substrate 10 may be calculated (obtained) by 180°-angle θ. For example, the chamfered portion 120 or the processed surface 121 may be an inclined surface inclined at an angle of about 105 degrees or more and 150 degrees or less from the surface of the substrate 10.

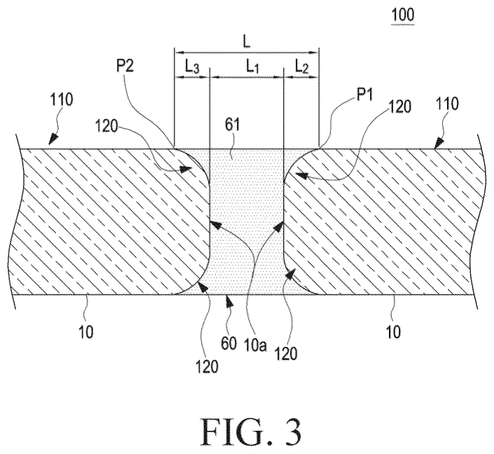

Further, for the chamfered portion 120, R processing for rounding with a predetermined curvature may be performed, as shown in FIG. 3, in addition to the cut shape with the flat cut surface as shown in FIG. 2.

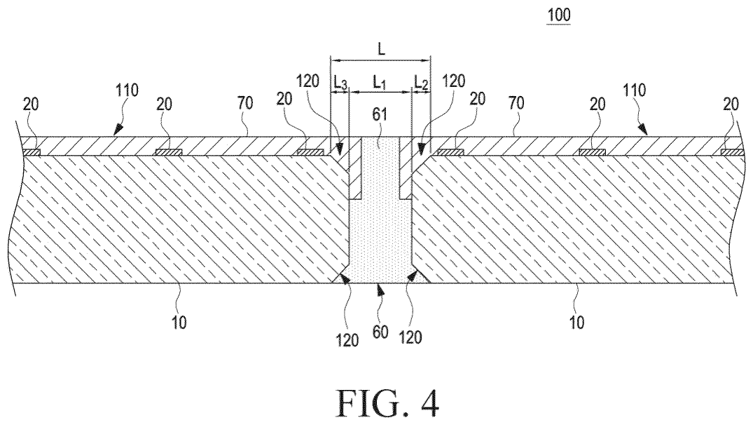

In the tiled display device 100, as shown in FIG. 4, the substrate 10 may be formed to cover the light emitting element 20 with a molding layer 70 having a thickness less than or equal to half of a thickness of the substrate 10. The molding layer 70 is formed of a resin such as, for example, a silicone resin or an epoxy resin, and a silicone resin may have relatively high heat resistance.

A method of forming a layered member for forming at least a portion of the molding layer 70 is not particularly limited, and may be formed by, e.g., a solution softening method, a melting softening method, a coating method, a sputtering method, a deposition method, an ion plating method, a chemical vapor deposition method (CVD method), etc.

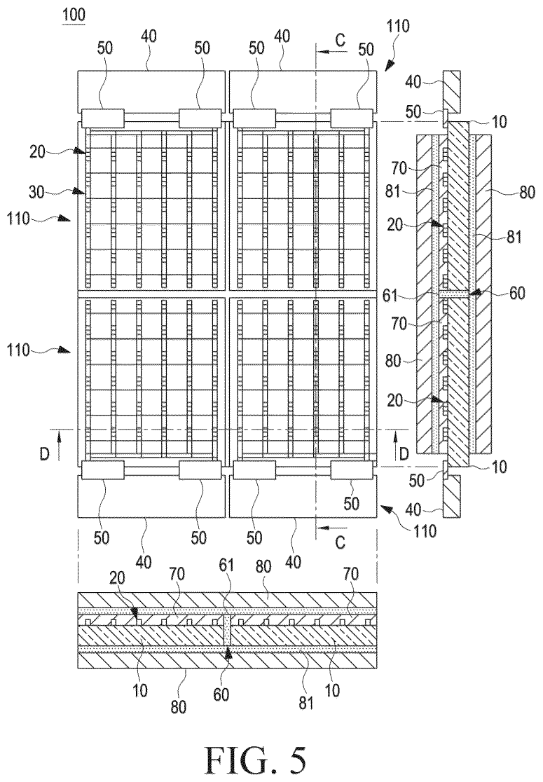

As shown in FIG. 5, in the tiled display device 100, a protective layer 80 may be formed on one side of the substrate 10 or two opposite sides of the substrate 10 to enhance strength such as impact resistance.

The protective layer 80 may be formed of, for example, a glass or organic resin film. The organic resin film may be, for example, a resin film that may be used as an optical film, and may be, e.g., polyester (PET), triacetyl cellulose (TAC), poly methyl methacrylate (PMMA), and poly carbonate (PC).

The adhesive layer 81 for adhering the protective layer 80 to the substrate 10 may be a resin from, for example, an acrylic resin, a urethane resin, an epoxy resin, a silicone resin, and a combination thereof.

The tiled display device 100 may include a low-reflective portion on at least one of the surface of the protective layer 80 or the surface of the seam portion 60. According to one or more embodiments, the tiled display device 100 may not include the low-reflective portion.

The low-reflective portion 90 may be a film formed of a low-reflective material (e.g., a black matrix resin containing a black material) or have predetermined surface processing has been performed to be low-reflective (e.g., anti-reflection (AR) treatment, low-reflection (LR) treatment, anti-glare (AG) treatment, or a combination thereof). For example, as the tiled display device 100 includes a low-reflective portion, reflection of external light on the tiled display device 100 may be suppressed, and the screen output from the tiled display device 100 may be more clearly recognized by the user.

For the refractive index of the transparent resin 61 filling the seam portion 60 of the tiled display device 100, the refractive indices nd, nf, and nc for the wavelengths of the D-line (589 nm) of sodium, F-line (486.13 nm) of hydrogen and hydrogen C-line (656.27 nm) may be measured using an Abbe refractometer based on the test method. Further, the interval L between the adjacent modules 110 in the tiled display device 100 may be measured using a microscope.

As described above, the tiled display device 100 according to one or more embodiments is formed by tiling modules 110 including, at least, the substrate 10, the light emitting element 20 mounted on the substrate 10, and the electrode unit 30 applying voltage to the light emitting element 20, and the seam portion 60 which is a gap between adjacent modules 110 is filled with the transparent resin 61. The transparent resin 61 has a refractive index difference ΔRI in the visible wavelength band between the substrate 10 and the transparent resin 61 in a range of −0.01≤ΔRI≤0.01. The interval L between the adjacent modules 110 is 0 μm<L≤300 μm. The transparent resin 61 may be formed of a resin from an epoxy resin, a silicone resin, an acrylic resin, and a combination thereof.

The corner portion 111 of the module 110 may have a chamfered portion 120 formed along the outer circumferential portion. The chamfered portion 120 may have an angle θ of 30°≤θ≤75° formed by the virtual line V passing through the surface of the chamfered portion 10 and the processed surface 121 of the chamfered portion 120.

In the tiled display device 100 according to one or more embodiments, a protective layer 80 may be formed on one side of the substrate 10 or two opposite sides of the substrate 10. The protective layer 80 may be formed of, for example, a glass or organic resin film. The adhesive layer 81 for adhering the protective layer 80 to the substrate 10 may be formed of a resin from an acrylic resin, a urethane resin, an epoxy resin, a silicone resin, and a combination thereof.

The tiled display device 100 according to one or more embodiments may have a low-reflective portion 90 to cover the seam portion 60 filled with the transparent resin 61. The low-reflective portion 90 may be formed on at least one of the protective layer 80 or the surface of the seam portion 60.

In the tiled display device 100 according to one or more embodiments, the transparent resin 61 may be a colored transparent resin having a transmittance of a range of −10≤transmittance of seam portion 60−transmittance of electrode unit 30≤10.

In the tiled display device 100 according to one or more embodiments, the substrate 10 may be formed to be provided on and cover the light emitting element 20 with a molding layer 70 having a thickness less than or equal to half of a thickness the substrate 10.

A tiled display device according to one or more embodiments may include modules having, at least, a substrate, a light emitting element mounted on the substrate, and an electrode unit applying a voltage to the light emitting element, and disposed adjacent to each other, a chamfered portion chamfered along an outer circumferential portion in a corner portion of the module and including an inclined surface or a curved surface, and a transparent resin filling an interval between the modules.

According to one or more embodiments, the transparent resin may have a refractive index difference ΔRI in a range of −0.01≤ΔRI≤0.01 between the substrate and the transparent resin in a visible wavelength band. According to one or more embodiments, the interval L between the adjacent modules may be 0 μm<L≤300 μm.

According to one or more embodiments, the chamfered portion may be an inclined surface inclined at an angle of greater than or equal to 105 degrees and less than or equal to 150 degrees from a surface of the substrate.

According to one or more embodiments, the tiled display device may further include a protective layer formed on one surface of the substrate or two opposite surfaces of the substrate.

By this configuration, it is possible to suppress the deterioration of seamlessness due to reflection of external light and refraction/scattering of transmitted light in the seam portion 60. Further, since the seam portion 60 may be formed to be seamless, it is possible to enhance seamlessness from the inclined direction as well as seamlessness from the front. Accordingly, the tiled display device 100 may have an outer appearance similar to one sheet of glass module and may be used from various sized displays.

Samples according to embodiments (embodiments 1 to 4) and samples according to related examples (related examples 1 to 8) were prepared according to the following processes.

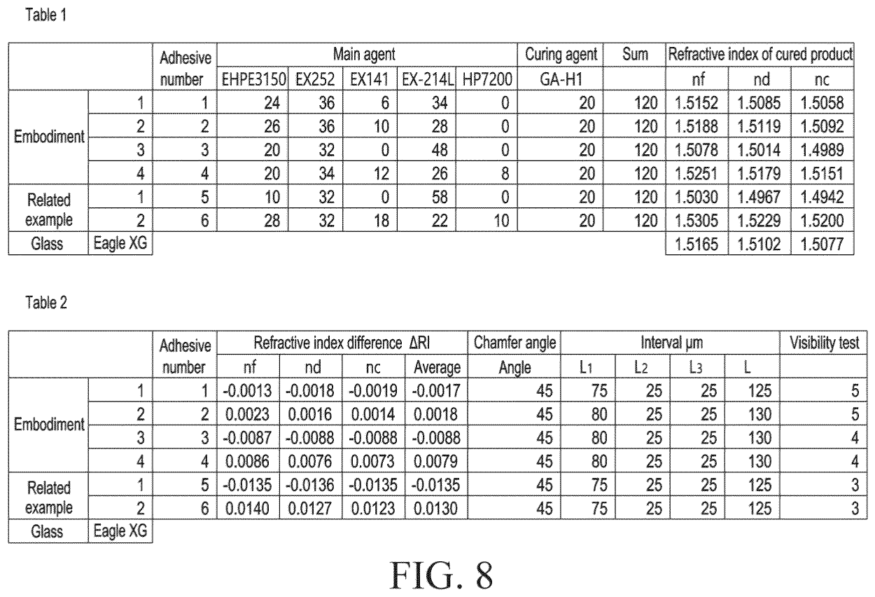

Six types of adhesives (adhesive 1 to adhesive 6) of the own formulation were prepared as the transparent resin to fill the seam portion between substrates. The weights of the respective main agents (e.g., main components) of the adhesives prepared are described below, and the respective refractive indices of the cured products of adhesives 1 to 6 and the refractive index of the glass substrate may be exemplified in Table 1 of FIG. 8.

Adhesive 1 was prepared by adjusting 24 g of EHPE3150, 36 g of Denacol EX-252, 6 g of Denacol EX-141, and 34 g of Denacol EX-214L to a uniform solution, as the main agent, and then mixing with 20 g of the curing agent GA-H-1.

Adhesive 2 was prepared by adjusting 26 g of EHPE3150, 36 g of Denacol EX-252, 10 g of Denacol EX-141, and 28 g of Denacol EX-214L to a uniform solution, as the main agent, and then mixing with 20 g of the curing agent GA-H-1.

Adhesive 3 was prepared by adjusting 20 g of EHPE3150, 32 g of Denacol EX-252, and 48 g of Denacol EX-214L to a uniform solution, as the main agent, and then mixing with 20 g of the curing agent GA-H-1.

Adhesive 4 was prepared by 20 g of EHPE3150, 34 g of Denacol EX-252, 12 g of Denacol EX-141, 26 g of Denacol EX-214L, and 8 g of Epicron HP-7200 to a uniform solution, as the main agent, and then mixing with 20 g of the curing agent GA-H-1.

Adhesive 5 was prepared by adjusting 10 g of EHPE3150, 32 g of Denacol EX-252, and 58 g of Denacol EX-214L to a uniform solution, as the main agent, and then mixing with 20 g of the curing agent GA-H-1.

Adhesive 6 was prepared by adjusting 28 g of EHPE3150, 22 g of Denacol EX-252, 18 g of Denacol EX-141, 22 g of Denacol EX-214L, and 10 g of Epicron HP-7200 to a uniform solution, as the main agent, and then mix with 20 g of the curing agent GA-H-1.

For the prepared adhesives 1 to 6, two 20 mm×30 mm×1 mm-thick fluoroplastic plates were prepared, one of which was hollowed out in the center in the size of 5 mm×20 mm, and the two plates were stacked and the edges were fixed with clips. Next, the hollowed-out area was filled with the adhesive and kept at room temperature for one day to cure. The cured adhesives 1 to 6 were measured at 25° C. using an Abbe refractometer for the refractive index nf at a wavelength of 486 nm, the refractive index nd at a wavelength of 589 nm and the refractive index nc at a wavelength of 656 nm, respectively. Further, the average value of the refractive index differences was calculated from the refractive index difference at each wavelength, which was used as the glass substrate. The respective refractive indices of the cured products of adhesive 1 to adhesive 6 and the refractive index of the glass substrate are shown in Table 1 of FIG. 8.

The samples of embodiments 1 to 4 were prepared as follows. After preparation, the interval L of each sample was measured using a microscope. The refractive index of the glass substrate used was as shown in Table 1 of FIG. 8.

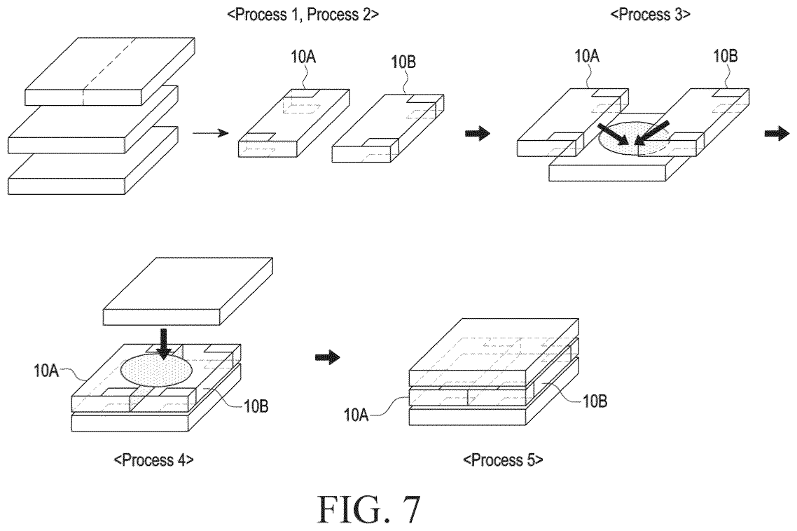

The samples of embodiments 1 to 4 were produced through processes 1 to 5, as shown in FIG. 7.

In process 1, three 50 mm×50 mm×0.5 mm-thick sheets, chamfered at a chamfer angle of 45° (chamfer width: 25 μm), were prepared as the glass substrates, one of which was cut in the center.

In process 2, a 50 μm-thick, 2 mm-wide gap-adjustment adhesive tape was applied from the surface to the opposite surface to cover the long-side and both-side end surfaces of the chamfered side of one cut glass substrate, preparing the first substrate 10A. Next, a 50 μm-thick, 2 mm-wide gap-adjustment adhesive tape was applied from the surface to the opposite surface to cover the long-side both-side end surfaces to the cut surface side of the other cut glass, preparing the second substrate 10B.

In process 3, an appropriate amount of adhesive was dropped onto the surface of one of the glass substrates that had not been cut, and with the chamfered side end surface of the first substrate 10A and the chamfered side end surface of the second substrate 10B facing each other, the adhesive was between them so that no air is entrapped and, in process 4, the remaining glass substrate was stacked so that no air is entrapped. In process 4, two pieces of gap adjustment adhesive tape (one at each end) are interposed between the first substrate 10A and the second substrate 10B.

In process 5, the stacked glass substrates were fixed with clips and kept at room temperature for one day to cure the adhesive, thus completing the sample preparation.

The specifications of the respective samples of embodiments 1 to 4 are as shown in Table 1 of FIG. 8.

The samples of related examples 1 and 2 were produced through processes 1 to 7, as shown in FIG. 7, similar to embodiments 1 to 4. Related example 1 used adhesive 5, and related example 2 used adhesive 6. After preparation, the interval L of each sample was measured using a microscope. The refractive index of the glass substrate used was as shown in Table 1 of FIG. 8. The specifications of the respective samples of related examples 1 and 2 are as shown in Table 1 of FIG. 8.

Related examples 3 to 5 were produced as follows. Related example 3 used adhesive 1, related example 4 used adhesive 3, and related example 5 used adhesive 4. After preparation, the interval L of each sample was measured using a microscope.

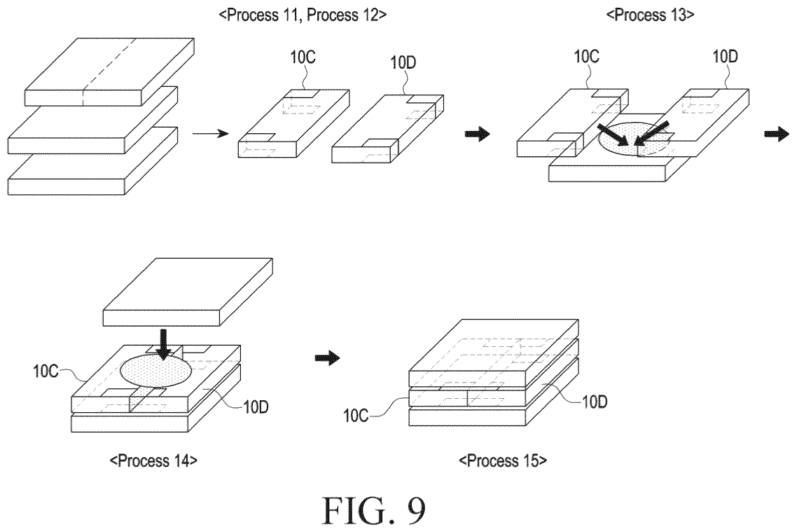

The samples of related examples 3 to 5 were produced through processes 11 to 15, as shown in FIG. 9.

In process 11, three 50 mm×50 mm×0.5 mm-thick sheets, chamfered at a chamfer angle of 45° (chamfer width: 25 μm), were prepared as the glass substrates, one of which was cut in the center.

In process 12, two sheets of 50 μm-thick, 2 mm-wide gap-adjustment adhesive tape were overlapped and applied from the surface to the opposite surface to cover the two opposite end surfaces of the long side to the chamfered side of both the cut glass substrates, preparing the first substrate 10C and the second substrate 10D.

In process 13, an appropriate amount of adhesive was dropped onto the surface of one of the glass substrates that had not been cut, and with the chamfered side end surface of the first substrate 10C and the chamfered side end surface of the second substrate 10D facing each other, the adhesive was between them so that no air is entrapped and, in process 14, the remaining glass substrate was stacked so that no air is entrapped. In process 13, eight pieces of gap adjustment adhesive tape (four at each end) are interposed between the first substrate 10C and the second substrate 10D.

In process 15, the stacked glass substrates were fixed with clips and kept at room temperature for one day to cure the adhesive, thus completing the sample preparation.

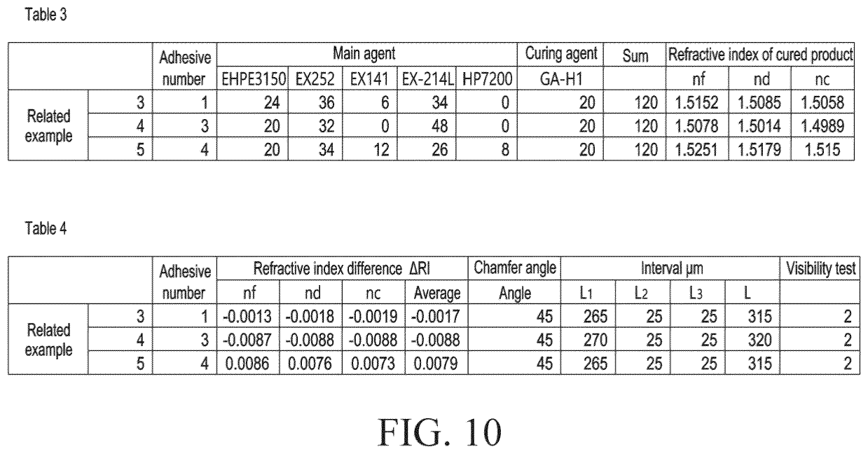

The specifications of the respective samples of related examples 3 to 5 are as shown in Table 3 of FIG. 10.

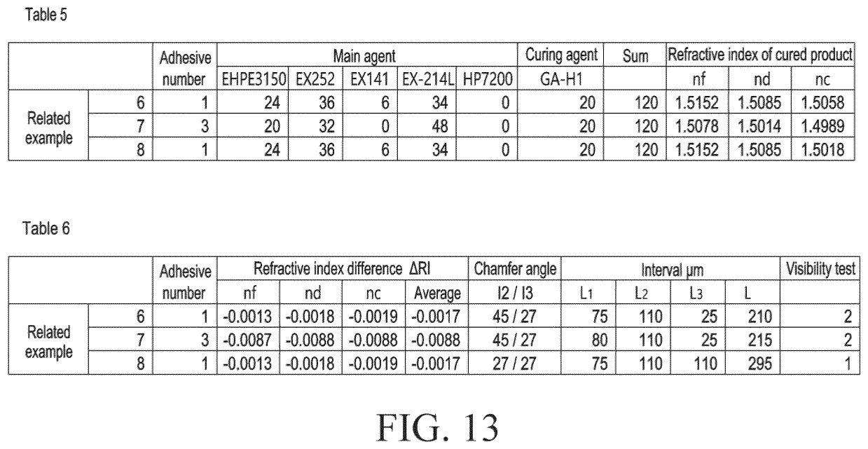

Related examples 6 to 8 were produced as follows. Related example 6 used adhesive 1, related example 7 used adhesive 3, and related example 8 used adhesive 1. After preparation, the interval L of each sample was measured using a microscope. The refractive index of the glass substrate used was as shown in Table 5 of FIG. 13.

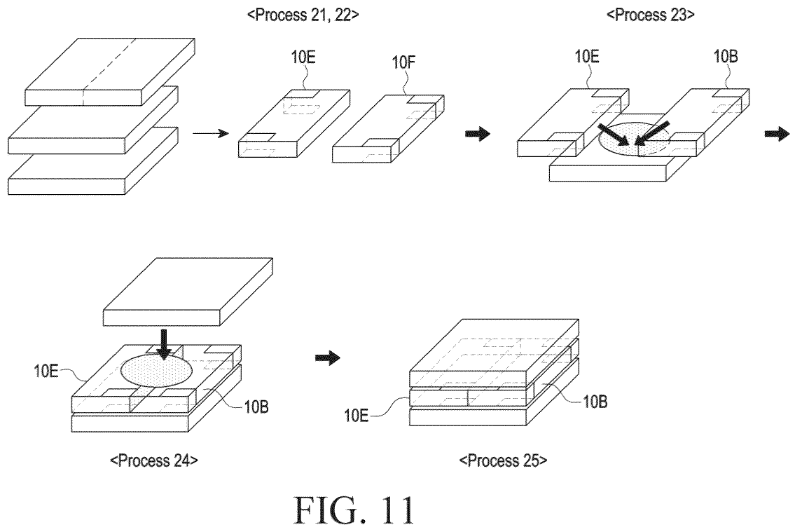

The samples of related examples 6 and 7 were produced through processes 21 to 25, as shown in FIG. 11.

In process 21, three 50 mm×50 mm×0.5 mm-thick sheets, chamfered at a chamfer angle of 27° (chamfer width: 110 μm), were prepared as the glass substrates, one of which was cut in the center.

In process 22, a 50 μm-thick, 2 mm-wide gap-adjustment adhesive tape was applied from the surface to the opposite surface to cover the two opposite end surfaces of the long side to the chamfered side of both the cut glass substrates, preparing the first substrate 10E and the second substrate 10F.

In process 23, an appropriate amount of adhesive was dropped onto the surface of one of the glass substrates that had not been cut, and with the chamfered side end surface of the second substrate 10B of embodiment 1 produced in process 3 and the chamfered side end surface of the first substrate 10E produced in process 22 facing each other, the adhesive was between them so that no air is entrapped and, in process 24, the remaining glass substrate was stacked so that no air is entrapped. In process 23, two pieces of gap adjustment adhesive tape (one at each end) are interposed between the second substrate 10B and the first substrate 10E.

In process 25, the stacked glass substrates were fixed with clips and kept at room temperature for one day to cure the adhesive, thus completing the sample preparation.

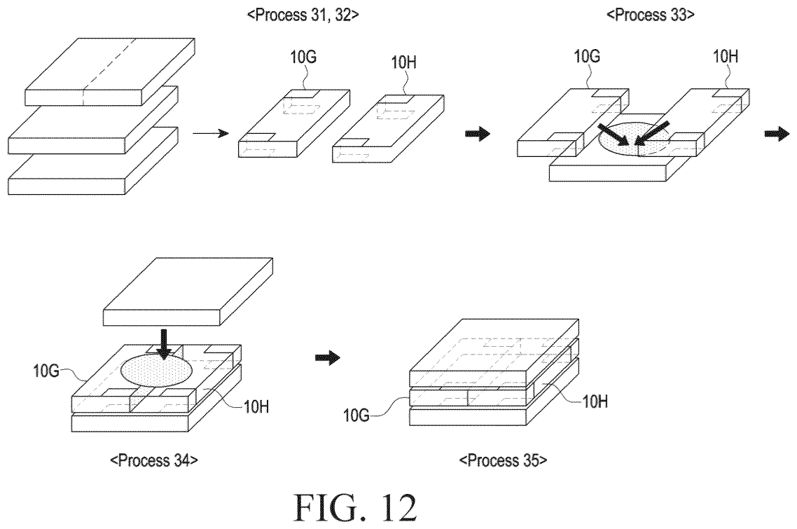

The sample of related example 8 were produced through processes 31 to 35, as shown in FIG. 12.

In process 31, three 50 mm×50 mm×0.5 mm-thick sheets, chamfered at a chamfer angle of 27° (chamfer width: 110 μm), were prepared as the glass substrates, one of which was cut in the center.

In process 32, a 50 μm-thick, 2 mm-wide gap-adjustment adhesive tape was applied from the surface to the opposite surface to be provided on and cover the both-side end surfaces of the long side to the chamfered side of one glass substrate cut at the chamfer angle of 27°, preparing the first substrate 10G. Next, it was applied from the surface to the opposite surface to be provided on and cover two opposite end surface of the long side to the cut surface side of the other glass substrate cut at a chamfer angle of 27°, preparing the second substrate 10H.

In process 33, an appropriate amount of adhesive was dropped onto the surface of one of the glass substrates that had not been cut, and with the chamfered side end surface of the first substrate 10G and the chamfered side end surface of the second substrate 10H facing each other, the adhesive was between them so that no air is entrapped and, in process 34, the remaining glass substrate was stacked so that no air is entrapped. In process 33, two pieces of gap adjustment adhesive tape (one at each end) are interposed between the first substrate 10G and the second substrate 10H.

In process 35, the stacked glass substrates were fixed with clips and kept at room temperature for one day to cure the adhesive, thus completing the sample preparation.

The specifications of the respective samples of related examples 6 to 8 are as shown in Table 5 of FIG. 13.

Each sample of the embodiments and related examples produced according to the above-described procedure was fixed to a window, and five subjects made sensory evaluations by observing the joint that serve as the seam portion of each substrate at various angles from a distance of 1 meter. The evaluation criteria were as follows: #1: the joint is clearly visible, #2: The joint is visible, #3: The joint is slightly visible, #4: The joint is faintly visible, and 5: The joint is barely visible, The rounded values averaged from the five subjects' evaluation values were adopted.

As shown in Table 2 of FIG. 8, the visibility test result of embodiment 1 was “#5”, the visibility test result of embodiment 2 was “#5”, the visibility test result of embodiment 3 was “#4”, and the visibility test result of embodiment 4 was “#4”. On the other hand, as shown in any one of Table 2 of FIG. 8, Table 4 of FIG. 10, and Table 6 of FIG. 13, the visibility test results of related example 1 and related example 2 were “#3, the visibility test results of related examples 3 to 7 were “#2”, and the visibility test results of related example 8 were “#1”.

In embodiments 1 to 4, the refractive index difference ΔRI in the visible wavelength band between the substrate and the transparent resin (adhesive 1 to adhesive 4) was in the range of −0.01≤ΔRI≤0.01, and the interval between the glass substrates corresponding to the interval L between the adjacent modules was in the range of 0 μm<L≤300 μm. In embodiments 1 and 2, since the refractive index difference ΔRI was in the range of −0.003≤ΔRI≤0.003, it is shown that the seamlessness of the seam portion was further achieved compared to embodiment 3 or 4.

Further, in embodiments 1 to 4, the angle θ formed by the virtual line passing through the surface of the substrate and the processed surface of the chamfered portion was in the range of 30°≤θ≤75°. In this regard, it was identified that the tiled display device acts on the enhancement of seamlessness and seamlessness of the seam portion by setting the chamfer angle of the chamfered portion to the above range in addition to the interval L between substrates and the refractive index difference ΔRI. Therefore, by using the technology of the present invention shown in embodiments 1 to 4, even the tiled structure of multiple modules may represent an outer appearance like a single glass module, which may be widely used from small to large displays.

On the other hand, in related examples 1 and 2, the refractive index difference ΔRI was outside of the range of −0.01≤ΔRI≤0.01, in related examples 3 to 5, the interval between glass substrates corresponding to the interval L between adjacent modules was out of the range of 0 μm<L≤300 μm, and in related examples 6 to 8, the chamfer angle of the chamfered portion was out of the range of 30°≤θ≤75°. As compared to embodiments 1 to 4, it was identified that related examples 1 to 8 had poor visibility test results and cannot present sufficient performance for sales products in terms of seamlessness. In this regard, it was identified that the refractive index difference ΔRI between the substrate and the transparent resin, the interval L between the adjacent modules, and the chamfer angle of the chamfered portion effect seamlessness enhancement and seamlessization, and in particular, the refractive index difference ΔRI between the substrate and the transparent resin and the interval between adjacent modules were substantial factors in achieving seamlessness enhancement and seamlessization.

While embodiments have been described with reference to the figures, it will be understood by those of ordinary skill in the art that various changes in form and details may be made therein without departing from the spirit and scope as defined by the following claims and their equivalents.

What is claimed is:

1. A tiled display device comprising:
modules adjacent to each other, each module comprising:
a substrate;
a light emitting element on the substrate;
an electrode configured to apply a voltage to the light emitting element; and
a chamfered portion comprising a surface chamfered along a corner portion of each module of the modules, the chamfered portion being inclined with respect to a surface of the substrate; and
a seam portion between adjacent modules of modules, the seam portion being filled with a transparent resin.

2. The tiled display device of claim 1, wherein a refractive index difference between a refractive index of the substrate and a refractive index of the transparent resin in a visible wavelength band is equal to or greater than −0.01 and equal to or less than 0.01, and
wherein a distance between the adjacent modules is greater than 0 μm and equal to or less than 300 μm.

3. The tiled display device of claim 2, wherein an angle between the processed surface of the chamfered portion and the surface of the substrate is equal to or greater than 30° and equal to or less than 75°.

4. The tiled display device of claim 1, wherein a protective layer is on a surface of the substrate or two opposite surfaces of the substrate.

5. The tiled display device of claim 4, further comprising a low-reflective portion on the seam portion filled with the transparent resin.

6. The tiled display device of claim 5, wherein the low-reflective portion is on at least one of a surface of the seam portion or a surface of the protective layer.

7. The tiled display device of claim 1, wherein the transparent resin is a colored transparent resin, and
wherein a different between a transmittance of the seam portion and transmittance of the electrode is equal to or greater than −10 and equal to or less than 10.

8. The tiled display device of claim 1, further comprising a molding layer on the light emitting element,
wherein a thickness of the molding layer is equal to or less than half of a thickness of the substrate.

9. The tiled display device of claim 1, wherein the transparent resin is one of an epoxy resin, a silicone resin, an acrylic resin, and a combination thereof.

10. The tiled display device of claim 4, wherein the protective layer is a glass or an organic resin film.

11. The tiled display device of claim 4, further comprising an adhesive layer adhering the protective layer to the substrate, the adhesive layer being one of an acrylic resin, a urethane resin, an epoxy resin, a silicone resin, and a combination thereof.

12. A tiled display device comprising:
modules adjacent to each other, each module comprising:
a substrate;
a light emitting element on the substrate,
an electrode configured to apply a voltage to the light emitting element; and
a chamfered portion chamfered along a corner portion of the module, the chamfered portion comprising an inclined surface or a curved surface; and
a transparent resin in an interval between adjacent modules of the modules,
wherein a refractive index difference between a refractive index of the substrate and a refractive index of the transparent resin in a visible wavelength band is equal to or greater than −0.01 and equal to or less than 0.01, and
wherein interval distance between the adjacent modules is greater than 0 μm and equal to or less than 300 μm.

13. The tiled display device of claim 12, wherein the chamfered portion is inclined with respect to a surface of the substrate at an angle equal to or greater than 105 degrees and equal to or less than 150 degrees.

14. The tiled display device of claim 12, further comprising a protective layer on a surface of the substrate or two opposite surfaces of the substrate.

15. An electronic device comprising:
modules adjacent to each other, each module comprising:
a substrate;
a light emitting element on the substrate;
an electrode configured to apply a voltage to the light emitting element; and
a chamfered portion comprising a surface chamfered along a corner portion of each module of the modules, the chamfered portion being inclined with respect to a surface of the substrate; and
a seam portion between adjacent modules of the modules, the seam portion being filled with a transparent resin.

16. The electronic device of claim 15, wherein a refractive index difference between a refractive index of the substrate and a refractive index of the transparent resin in a visible wavelength band is equal to or greater than −0.01 and equal to or less than 0.01, and
wherein interval distance between the adjacent modules is greater than 0 μm and equal to or less than 300 μm.

17. The electronic device of claim 16, wherein an angle between the processed surface of the chamfered portion and the surface of the substrate is equal to or greater than 30° and equal to or less than 75°.

18. The electronic device of claim 15, wherein a protective layer is on a surface of the substrate or two opposite surfaces of the substrate.

19. The electronic device of claim 18, further comprising a low-reflective portion on the seam portion filled with the transparent resin.

20. The electronic device of claim 19, wherein the low-reflective portion is on at least one of a surface of the seam portion or a surface of the protective layer.
